(19) United States
(12) Patent Application Publication
(10) Pub. No.: US 2001/0009792 A1
(43) Pub. Date: Jul. 26, 2001

(54) Reduced gate length transistor structures and methods for fabricating the same

(76) Inventors: Subhas Bothra, San Jose, CA (US); Harlan Lee Sur JR., San Leandro, CA (US); Samar Saha, Milpitas, CA (US)

Correspondence Address: MARTINE PENILLA & KIM, LLP, 710 LAKEWAY DRIVE, SUITE 170, SUNNYVALE, CA, 94085, US

(21) Appl. No.: 09/764,731

(22) Filed: Jan. 16, 2001

Related U.S. Application Data
(62) Division of application No. 09/162,321, filed on Sep. 28, 1998.

(51) Int. Cl. H01L 21/3205; H01L 21/4763

(52) U.S. Cl. 438/302; 438/305; 438/585

(57) ABSTRACT

A semiconductor transistor includes a modified gate structure defined over a substrate, such structure includes a polysilicon inner region having a top surface gate length and a bottom surface gate length disposed over the substrate. The bottom surface gate length has a modified gate length value that is shorter than a gate length value of the top surface gate length. A spacer defines a border around the polysilicon inner region, the border is configured to define the modified gate length value. The modified gate length value is less than the limit of the photolithography that is used to manufacture the transistor structure. The value (in microns) of the modified gate length L_{G} is less than the lithography-limited gate length. Additionally, after the at least one spacer is defined, and thus, after the modified gate length is defined, a source/drain extension is located substantially below the spacer that defines the border around the polysilicon inner region. The source/drain extensions may further define the modified gate length. A method for making the transistor structure includes providing on a substrate a gate-defining layer having a gate-defining region which is provided with a critical dimension defining an initial value of a length of the gate-defining region of the transistor structure. The minimum critical dimension is limited by photolithography characteristics. Another operation reduces the initial value of the critical dimension by depositing into the gate-defining region a gate-length reducer structure to define a value of a modified gate length L_{MG}.

### BACKGROUND OF THE INVENTION

1. Field of the Invention

The present invention relates to the manufacture of semiconductor devices having sub-micron gate lengths. More particularly, the present invention relates to techniques for improving the fabrication of transistor gates to provide gate length values that are smaller than those afforded by the limits of conventional photolithography techniques, and to transistors having such gate length values.

2. Description of the Related Art

In the manufacture of semiconductor integrated circuits, many well-known photolithography techniques are used to pattern the various functional features on different levels of an integrated circuit chip. Generally, photolithography involves selectively exposing regions of a photoresist-coated silicon wafer to a light radiation pattern, and then developing the exposed photoresist in order to selectively protect regions of wafer layers, such as metallization layers, oxide dielectric layers, polysilicon layers, silicon layers, etc., from subsequent etching operations.

As is well known, photoresist is a light radiation-sensitive material that is typically spin-coated over a selected layer of a silicon wafer. According to the type of photoresist material, the chemical reaction to light radiation during exposure either causes the material to become more soluble (positive type) and thus more easily removed during the development process, or to become less soluble (negative type) when exposed to radiation, thereby enabling the removal of non-exposed regions. Although a traditional I-Line photolithography process works well for patterning features in the 0.35 micron technology and larger, as feature sizes in integrated circuits continue to shrink, the patterned photoresist has been exhibiting a number of resolution abnormalities.

To address this limitation, a number of common photolithography processes are now implementing deep ultra violet (“DUV”) wavelengths (e.g., 248 nm). As a result of implementing DUV wavelengths in the photolithography process, a number of chemically amplified DUV photoresists were also developed to better interact with the DUV wavelengths. Although the new chemically amplified DUV photoresists work relatively well, as smaller and smaller feature sizes are designed for higher performance integrated circuit devices, the resolution of these high performance designs have been exemplifying less than acceptable resolution due to poor photoresist development.

To exemplify the results of this problem, FIGS. 1A and 1B show a transistor structure 102 fabricated using photoresist patterning capable of providing the transistor structure 102 with a minimum gate length (L_{G}) of about 0.15 microns. The gate length L_{G} is defined by spaced, lightly doped drain regions 103 located under respective spacers 104. A polysilicon gate layer 106 is provided inside the spacers 104 and over a gate oxide layer 107. In order to pattern the polysilicon gate layer 106, FIG. 1B shows a photoresist layer 108 spin-coated and patterned on top of the polysilicon layer 106. Thus, the photoresist layer 108 is selectively exposed to the DUV light, and the photoresist layer 108 is developed. Ideally, all of the photoresist layer 108 lying in exposed regions should be vertically developed down. FIG. 1B shows that, unfortunately, as is known in the art, a residue 109 of photoresist remains near the lower portions 112 producing what is known as a “footing” effect and other profile abnormalities. Specifically, footings 113 remain near the interface of the polysilicon layer 106 with the photoresist layer 108, and a photoresist film (not shown) also sometimes remains on the surface of the polysilicon gate layer 106. Of course, when the photoresist layer 108 fails to develop as ideally desired, the etching of the underlying polysilicon layer 106 will not reflect the desired patterns. As shown in FIG. 1A, if the photoresist layer 108 had been ideally developed, the etched profile of the polysilicon gate layer 106 would most likely be defined by lines 114 (shown as dashed lines). However, when the footings 113 result (or other abnormalities that push the limits of photolithography), the true etched profile of the polysilicon gate layer 106 would most likely be defined by lines 116 (shown as dash-dot lines). The footings 113, for example, may result in a gate length L_{G} equal to the spacing between the dash-dot lines 116 rather than the shorter spacing between the dash-dash lines 114. Since the dash-dot lines 116 are spaced further apart than the dash-dash lines 114, FIG. 1A shows the transistor structure 102 as having a longer gate length L_{G} than would result if the shorter length between the dash-dash lines 114 defined the gate length L_{G}.

The lithography which limits the gate length L_{G} to not less than about 0.15 microns (as defined by the dash-dot lines 116) is referred to as a “gate-length limitation”, and is also applicable to chemically enhanced DUV techniques. Typically, with the described DUV techniques, gate lengths L_{G} are generally limited to no less than about 0.15 microns. As described below, the about 0.15 micron value of the gate length L_{G} is said to be the “limit of the photolithography” that is used to manufacture the transistor structure 102, and the about 0.15 micron value is said to be the “lithography-limited gate length”. As applied to other techniques which may supersede even the chemically enhanced DUV techniques, it is expected that there will be a certain micron value of the gate length L_{G} below which the gate length L_{G} cannot reliably be made. Such certain micron value of the gate length L_{G} would also be said to be the “limit of the photolithography” that is used to manufacture the transistor structure 102, and such certain micron value would be said to be the “lithography-limited gate length”.

Further, as shown in FIG. 1A, the spacers 104 may be provided on source/drain regions 118 of the transistor structure 102 outside of the polysilicon gate 106. In the fabrication of such transistor structure 102, the gate length L_{G} is first established by the dimension (shown being horizontal) of the polysilicon layer 106 of the gate, and then the spacers 104 are formed. As a result, the spacers 104 do not modify, or otherwise contribute to, the value of the gate length L_{G}. Therefore, the micron value of the gate length L_{G} defined by the polysilicon gate 106 without modification by the spacers 104, is also at the “limit of the photolithography” that is used to manufacture the transistor structure 102, and such micron value is the “lithography-limited gate length”.

In view of the foregoing, there is a need for methods and apparatus for improving the manufacture of semiconductor devices having sub-micron gate lengths, and for improving such devices having such sub-micron gate lengths, in order to provide gate lengths less than the limit posed by the photolithography that is used to manufacture the devices.

### SUMMARY OF THE INVENTION

Broadly speaking, the present invention fills these needs by providing improved manufacture of semiconductor devices having sub-micron gate lengths, and improved devices having such sub-micron gate lengths, in which the gate lengths are less than the limit of the photolithography that is used to manufacture the devices. Such gate lengths and gate length values are provided by at least one spacer within a gate region, wherein the at least one spacer defines a border around a polysilicon inner region. Additionally, a source/drain extension may be implanted after the spacers are formed and may be located substantially below the at least one spacer. It should be appreciated that the present invention can be implemented in numerous ways, including as a process, as a semiconductor device, or a method. Several inventive embodiments of the present invention are described below.

In one embodiment, a semiconductor transistor structure includes a substrate and a modified gate structure defined over the substrate. The modified gate structure may include a polysilicon inner region having a top surface gate length and a bottom surface gate length that is disposed over the substrate. The bottom surface gate length may have a modified gate length value that is shorter than a gate length value of the top surface gate length of the polysilicon inner region. Further, at least one spacer may define a border around the polysilicon inner region, the border being configured to define the modified gate length value that is shorter than the gate length of the top surface gate length. In terms of the above-described gate lengths that are less than the limit of the photolithography that is used to manufacture the devices, the modified gate length value is less than the limit of the photolithography that is used to manufacture the transistor structure. Also, the value (in microns) of the modified gate length L_{G} is less than the lithography-limited gate length. Additionally, after the at least one spacer is defined, and thus, after the modified gate length is defined, a source/drain extension may be located substantially below the at least one spacer that defines the border around the polysilicon inner region. The source/drain extensions may further define the modified gate length.

In another embodiment, a method for making a semiconductor transistor structure includes operations of providing a substrate and providing on the substrate a gate-defining layer having a gate-defining region. The gate-defining region is provided with a critical dimension defining an initial value of a length of the gate-defining region of the transistor structure. The critical dimension has a minimum value that is limited by at least the photolithography characteristics of the operation of providing the gate-defining layer with the gate-defining region. Another operation reduces the initial value of the critical dimension by depositing into the gate-defining region a gate-length reducer structure to define a value of a modified gate length L_{MG} of the transistor structure. The modified gate length L_{MG} of the transistor structure is substantially less than the initial value of the critical dimension. Another aspect of the method includes the critical dimension extending in a given direction relative to and over the substrate, and the gate-length reducer structure having a reducer dimension in the given direction. This aspect of the method may also include the operation of directing implant material through the gate-length reducer structure and into the substrate to define a source-drain extension region in the substrate, the source-drain extension region being under the gate-length reducer structure. The substrate may be provided with a surface, and the directing operation may further include directing the implant material along selected paths. The selected paths may be at an angle relative to the surface of the substrate so that the implant material is directed through and under the gate-length reducer structure. The angle of the selected paths, the dosage of the dopant material, and the energy of the dopant material may be selected according to the value of the gate-length reducer dimension in the given direction.

As an advantage, the above-described values of the modified gate lengths are less than the limit of the photolithography that is used to manufacture the devices. Therefore, current lithographic techniques may be used in the fabrication of the devices, yet the need for gate lengths that are not lithography-limited may be met. Further, the micron value of the modified gate length (that is shorter than the gate length of the top surface gate length) is less than the lithography-limited gate length, which also allows one to meet the need for gate length values less than the lithography-limited gate length. Additionally, the ability to provide source/drain extensions located substantially below the at least one spacer that defines the border around the polysilicon inner region enables the source/drain extensions to further define the value of the modified gate length.

Other aspects and advantages of the invention will become apparent from the following detailed description, taken in conjunction with the accompanying drawings, illustrating by way of example the principles of the invention.

### BRIEF DESCRIPTION OF THE DRAWINGS

The present invention will be readily understood by the following detailed description in conjunction with the accompanying drawings, wherein like reference numerals designate like structural elements.

FIG. 1A shows a prior art transistor structure fabricated using photoresist patterning capable of providing the transistor structure with a minimum lithography-limited gate length (L_{G}).

FIG. 1B shows that a residue of photoresist produces a footing effect, resulting in the transistor structure shown in FIG. 1A as having a longer gate length L_{G} than would result without the footing effect or other limitations, such that the micron value of the length gate L_{G} is the limit of the photolithography used to manufacture the depicted transistor structure.

FIG. 2A is a cross sectional view of a semiconductor substrate having a gate-defining layer deposited thereon as a first operation of a process that provides improved manufacture of semiconductor devices having sub-micron modified gate lengths in accordance with one embodiment of the present invention.

FIG. 2B shows the next operations in the process shown in FIG. 2A, in which photoresist is coated on the gate-defining layer and an etching operation is used to define a pattern of the gate-defining layer that will be removed.

FIG. 2C shows the next operations in the process shown in FIGS. 2A and 2B, in which the etching operation has removed a certain portion of the gate-defining layer to define a gate region.

FIG. 2D shows the next operations in the process shown in FIGS. 2A through 2C, in which a silicon nitride layer is deposited on the patterned gate region and substrate.

FIG. 2E shows the structure after an etching operations is performed to define the spacers and the gate oxide is grown, in accordance with one embodiment of the present invention.

FIG. 2F shows a next operation in the process shown in FIGS. 2A through 2E in which a polysilicon layer is deposited on the structure shown in FIG. 2E.

FIG. 2G shows the next operations in the process shown in FIGS. 2A through 2F, including the results of a chemical mechanical operation which removes the polysilicon layer from the gate-defining layer, leaving the polysilicon layer in the gate region within the spacers.

FIG. 2H shows further operations of the process shown in FIGS. 2A through 2G, including an oxide etch for removing the polysilicon layer from adjacent to the spacers.

FIG. 2I shows further operations of the process shown in FIGS. 2A through 2H, including implant operations for implanting source/drain extensions below the spacers to further define the value of the modified gate length of the transistor structure.

FIG. 2J shows further operations of the process shown in FIGS. 2A through 2I, including second source-drain implant operations for implanting source and drain dopants into and deeper than the source/drain extensions to define source-drain diffusion regions.

FIG. 3A illustrates the transistor structure, including the source-drain diffusion regions and the source-drain extensions beneath the gate structure, wherein the source-drain extensions and the spacers define the value of the modified gate length of the gate structure which are less than the limit of the photolithography that is used to manufacture the transistor structures.

FIG. 3B shows the transistor structure resulting from the operations described with respect to FIGS. 2A through 2J, and 3A, including an oxide layer, conductive vias, and a metallization layer for completing interconnects.

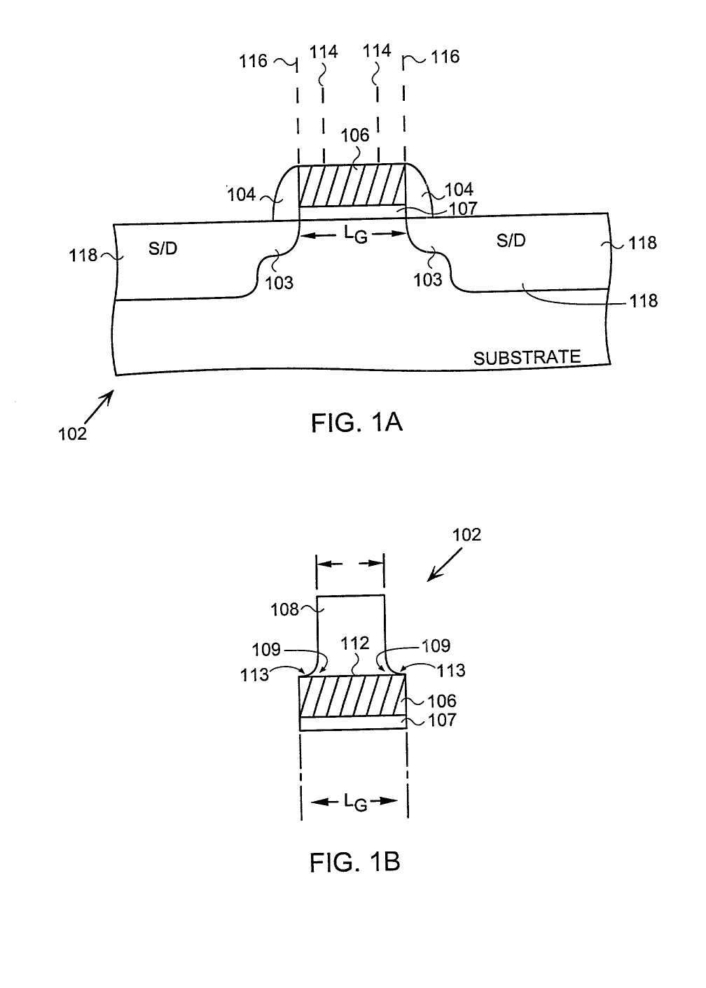

### DETAILED DESCRIPTION OF THE PREFERRED EMBODIMENTS

An invention for improved manufacture of semiconductor devices having sub-micron gate lengths, and improved devices having such sub-micron gate lengths, in which modified gate lengths are less than the limits of the photolithography that is used to manufacture the devices, and the modified gate length values are less than the limits of such photolithography, is disclosed. Such modified gate lengths and values of modified gate length are provided by at least one spacer within a gate region, wherein the at least one spacer defines the border around a polysilicon inner region. Additionally, a source-drain extension may be located substantially below the at least one spacer. In the following description, numerous specific details are set forth in order to provide a thorough understanding of the present invention. It will be understood, however, to one skilled in the art, that the present invention may be practiced without some or all of these specific details. In other instances, well known process operations have not been described in detail in order not to obscure the present invention.

In one embodiment, a semiconductor transistor structure includes a substrate and a modified gate structure defined over the substrate. The modified gate structure may include a polysilicon inner region having a top surface gate length, and a bottom surface gate length that is disposed over the substrate. The bottom surface gate length has a value of a modified gate length that is shorter than a value of a gate length of the top surface gate length of the polysilicon inner region. Further, at least one spacer may define a border around the polysilicon inner region, the border being configured to define a value of a modified gate length that is shorter than the value of a gate length of the top surface gate length. In terms of the above-described modified gate lengths that are less than the limit of the photolithography that is used to manufacture the devices, the value of the modified gate length (that is shorter than the value of the gate length of the top surface gate length) is less than the limit of the photolithography that is used to manufacture the transistor structure. Also, the micron value of the modified gate length is less than the lithography-limited gate length. Additionally, a source-drain extension may be located substantially below the at least one spacer that defines the border around the polysilicon inner region, and the source-drain extension may further define the modified gate length.

In another embodiment, a method for making a semiconductor transistor structure includes operations of providing a substrate, and providing on the substrate a gate-defining layer. The layer has a gate-defining region provided with a critical dimension defining an initial gate-length value. The critical dimension has a minimum value that is limited by at least the photolithography characteristics of the operations of providing the gate-defining layer and the gate-defining region. Another operation reduces the initial gate-length value by depositing into the gate-defining region a gate-length reducer structure (such as a spacer) to define a modified gate length of the transistor structure. The modified gate length of the transistor structure is substantially less than the initial value of the critical dimension. Another aspect of the method includes the critical dimension extending in a given direction relative to and over the substrate, and the reducer structure having a gate-length reducer dimension in the given direction. This aspect of the method may also include the operation of directing implant material through the gate-length reducer structure and into the substrate to define a source-drain extension region in the substrate. The source-drain extension region is under the gate-length reducer structure. The substrate may be provided with a surface, and the implant directing operation may further include directing the implant material along selected paths, the selected paths being at an angle relative to the surface of the substrate. In this manner, the implant material is directed under the gate-length reducer structure, with the angle of the selected paths, and the implant dosage and energy being selected according to the value of the gate-length reducer dimension in the given direction.

As an advantage, the above-described modified gate lengths are less than the limit of the photolithography that is used to manufacture the devices. Therefore, current lithographic techniques may be used in the fabrication of the devices, yet the need for gate lengths that are not lithography-limited may be met. Additionally, the ability to provide source-drain extensions located substantially below the at least one spacer that defines the border around the polysilicon inner region enables the source-drain extensions to further define the modified gate length.

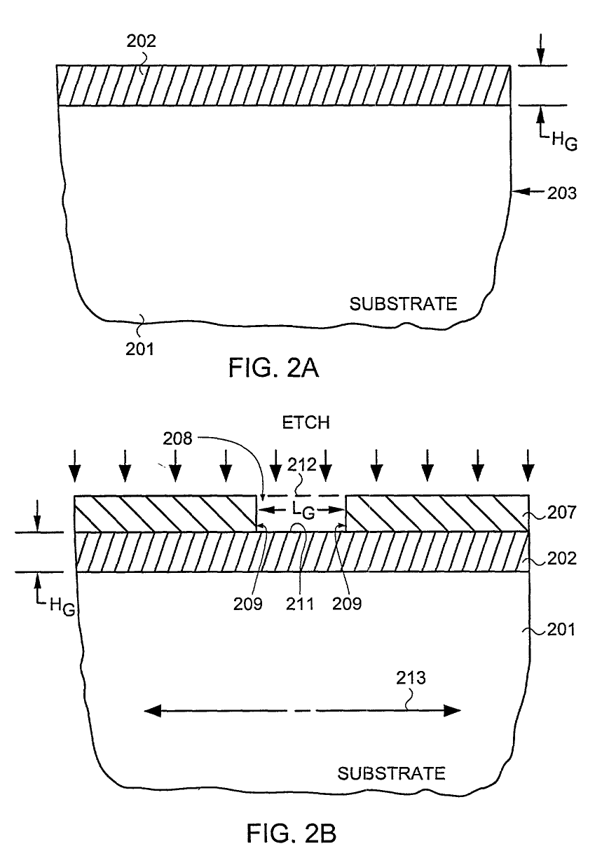

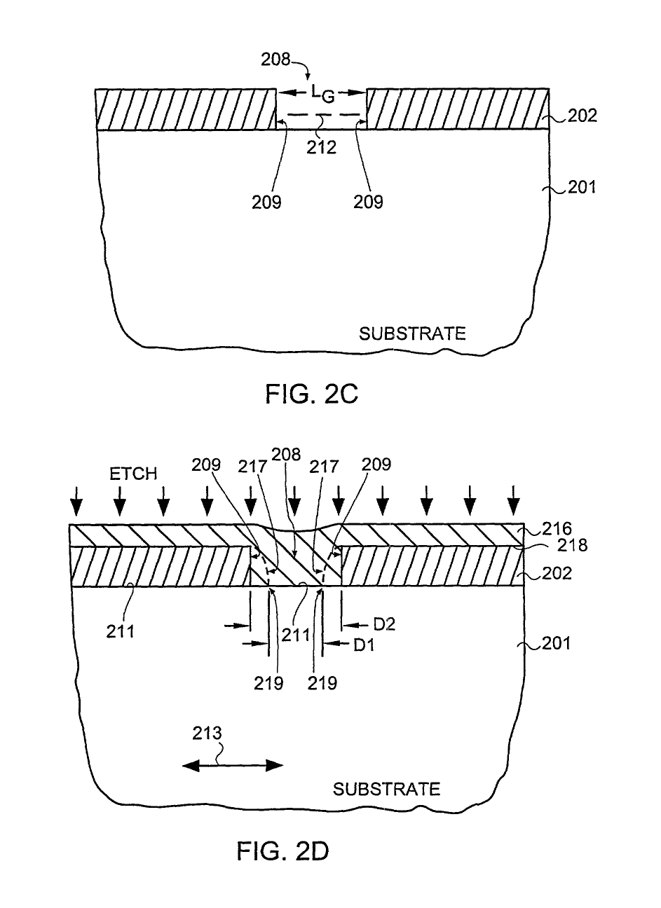

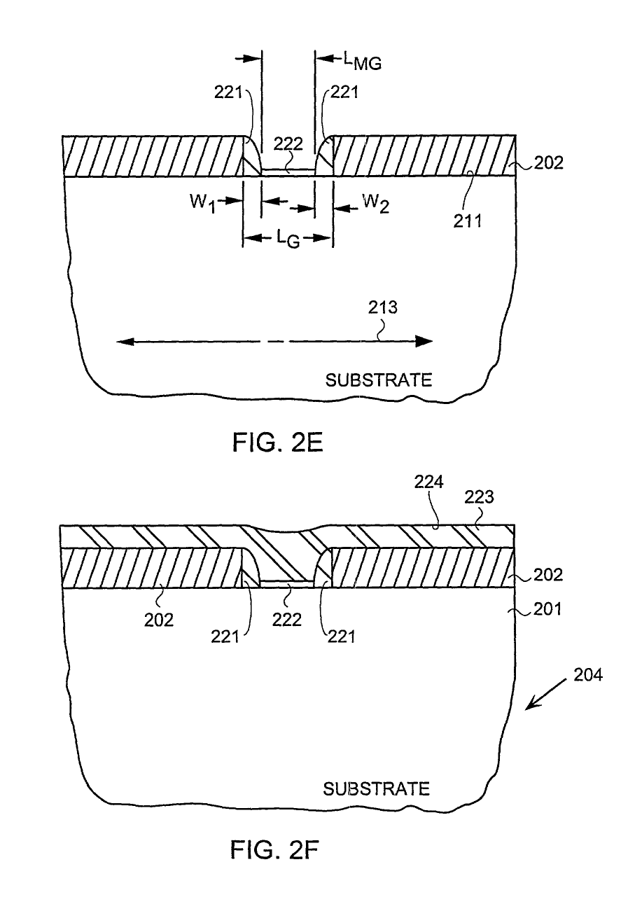

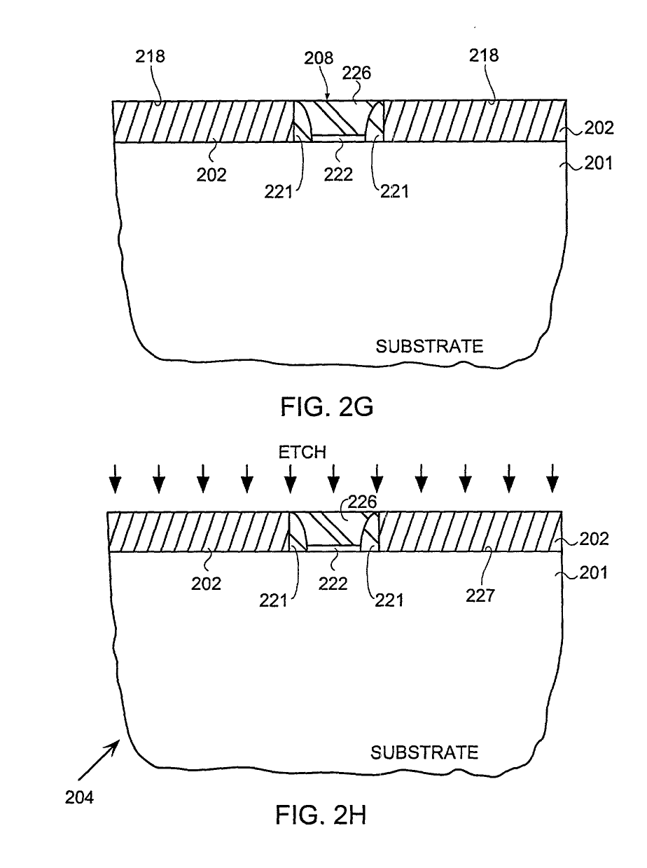

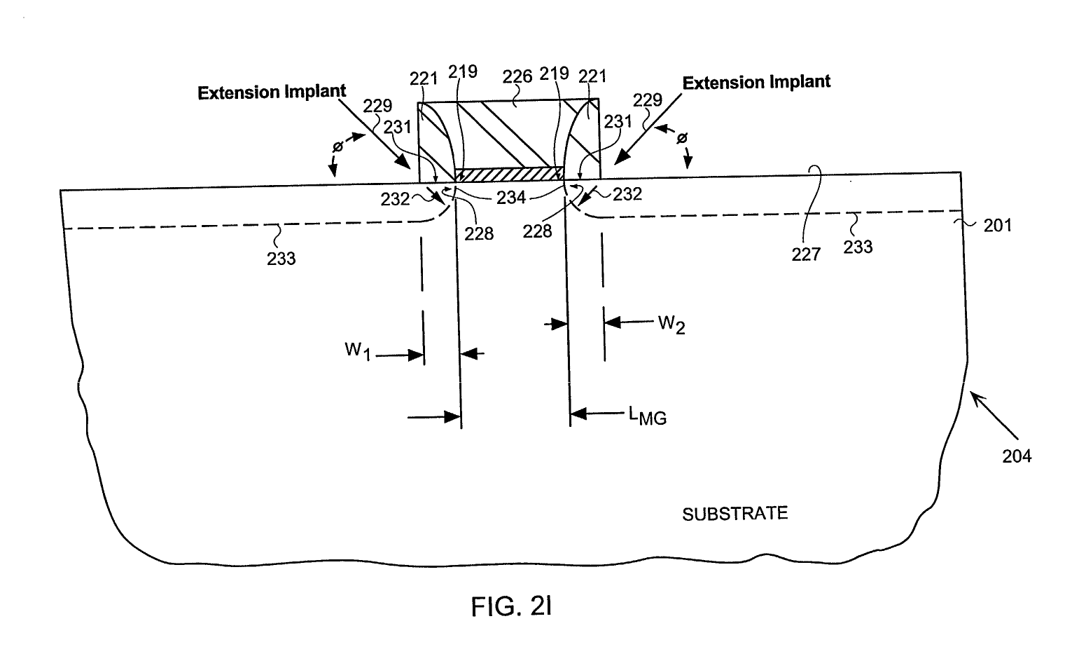

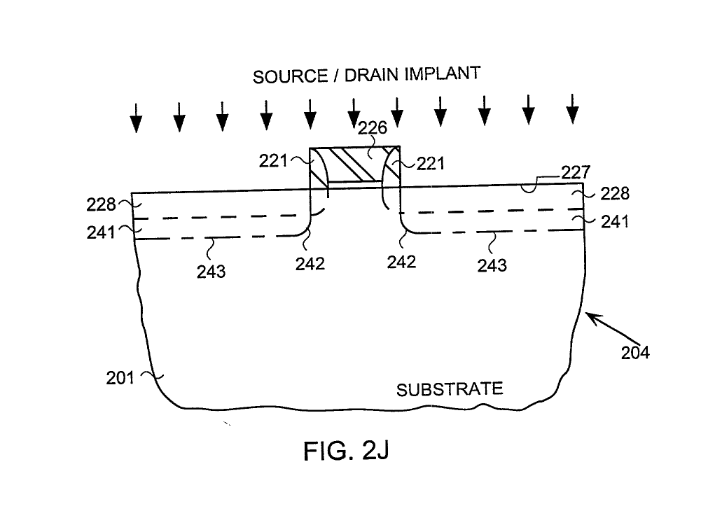

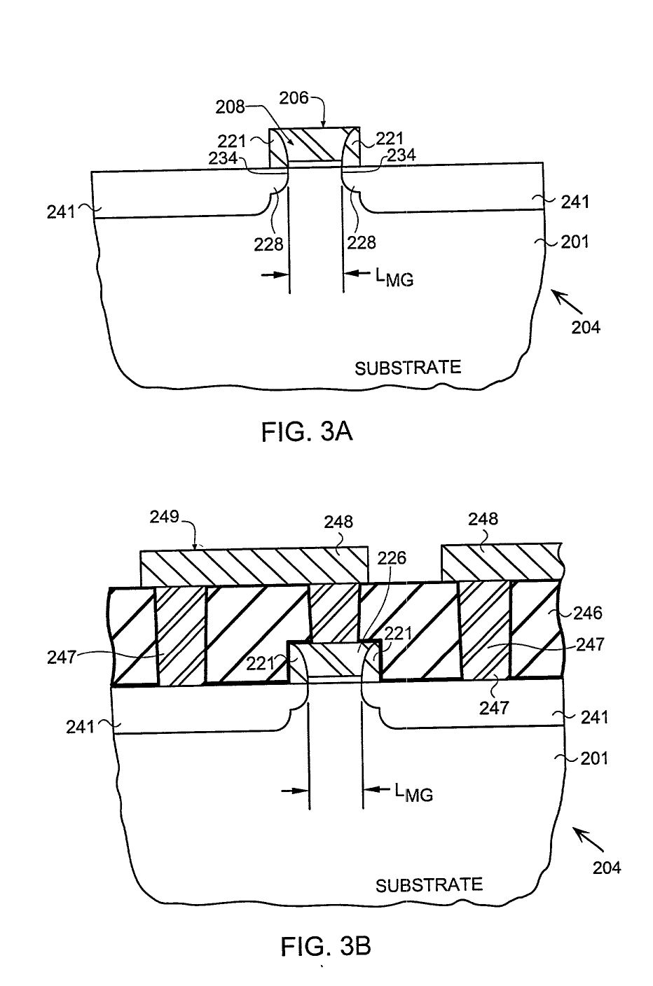

FIG. 2A shows a cross sectional view of a semiconductor substrate 201. A gate-definition layer 202 is deposited on the substrate 201 as a first operation of a process that provides improved manufacture of semiconductor devices 203, such as semiconductor transistor structures 204 (FIG. 3A). The semiconductor transistor structures 204 may include a gate 206 (FIG. 3A) having a sub-micron, modified gate length L_{MG}, and gate lengths L_{MG} are described as “modified” because the gate lengths are less than the limit of the photolithography that is used to manufacture the devices 203. In a preferred embodiment, the gate-definition layer 202 is fabricated from silicon dioxide, and is referred to as an oxide layer. In one embodiment, the silicon dioxide is preferably one of an LPCVD, PECVD, and an HDPCVD deposited material. The thickness of the oxide layer 202 determines the thickness, or gate height H_{G}, of the gate 206 of the semiconductor device 204.

FIG. 2B shows the next operations in the process shown in FIG. 2A, in which conventional photolithography patterning and etching techniques are used. A photoresist material 207 is spin coated on the oxide layer 202. Such patterning technique then causes the photoresist material 207 to be selectively removed from the oxide layer 202 so that the photoresist material 207 serves as a mask and exposes areas of the oxide layer 202 which are to be removed. One such area to be removed is shown as a gate region 208 having opposed sides 209 which define the value of an initial gate length L_{G} and a bottom 211. A plasma etch operation is used to remove the oxide layer 202, leaving the gate region 208 having the gate height H_{G}, the sides 209 and the bottom 211 at the desired location for the gate 206 of the transistor structure 204. The opposed sides 209 are spaced in the direction of an axis 212, which axis 212 is parallel to a gate direction (shown by arrow 213) in which the gate lengths L_{G} and L_{MG} extend.

FIG. 2C illustrates the next operations in the process shown in FIGS. 2A and 2B. Following the plasma etch operation, the remaining photoresist 207 is stripped from the remaining oxide layer 202. FIG. 2C shows the remaining oxide layer 202 having the sides 209 which define the extent in the direction of the gate axis 212 of the gate region 208.

FIG. 2D illustrates a preferred embodiment of the present invention, in which a layer 216 of silicon nitride material is deposited over the oxide layer 202 and into the gate region 208, including on the bottom 211, which is a portion of the exposed substrate 201 within the gate region 208. Such silicon nitride material layer 216 is used when the underlying gate-defining layer 202 is silicon dioxide, for example. To denote the result of a future operation, FIG. 2D includes dashed curved lines 217 extending upwardly from the bottom 211 and outwardly toward the opposed sides 209. Each curved line 217 meets an upper, or top, surface 218 of the oxide layer 202 adjacent to one of the opposed sides 209. As shown, intersections 219 of the curved lines 217 with the bottom 211 are spaced in the gate direction (see arrow 213) by the modified gate length L_{MG} The term “modified” indicates that the distance D1 between such intersections 219 is substantially shorter than (and is thus “modified” as compared to) a distance D2 extending in the gate direction (see arrow 213) between the opposed sides 209.

Additionally, FIG. 2D shows a plasma etch operation which is performed to remove the silicon nitride layer 216 from the top surface 218 of the oxide layer 202 and from a portion of the gate region 208, as described below. Upon completion of this plasma etch operation, a portion of the silicon nitride layer 216 remains in the form of spacers 221 (FIG. 2E). In this preferred embodiment, the etching of the silicon nitride layer 216 will preferably be performed using the exemplary etching chemistries and conditions illustrated in Table 1 below.

TABLE 1
Silicon Nitride CF₄/O₂/Ar
Etch Chemistry

| | | | | | | (He) |
|---|---|---|---|---|---|---|
| | | | | | | backside |
| | Power | | Flow | | Pressure | pressure |
| | Watts | | SCCM | Rates | MTorr | Torr |
| Preferred Range | 300-1200 | Ar | CF₄ | O₂ | 100-300 | 5-20 |
| | | 50-200 | 10-120 | 5-50 | | |
| More Preferred | 500-1000 | Ar | CF₄ | O₂ | 150-250 | 7-13 |
| Range | | 80-120 | 30-90 | 10-20 | | |
| Most | 700 | Ar | CF₄ | O₂ | 200 | 10 |
| Preferred | | 100 | 60 | 15 | | |

In order to ensure that the material of the silicon nitride layer 216 has been removed from the top surface 218, an endpoint signal is monitored. After endpoint, a 15% overetch is performed. Similarly, any other percentage overetch is also measured relative to an actual 15 percent etch time.

In this embodiment, due to experimentally determined etch rate selectivities, the etching chemistries used to etch through the material of the silicon nitride layer 216 will only etch through the layer 202 of silicon dioxide at about one-third the rate of etching the silicon nitride layer 216. As a result, when about 750 angstroms of the silicon nitride layer 216 is etched, a subsequent 15 percent overetch will only etch about 37.5 angstroms of the silicon dioxide layer 202 (i.e., 112.5/3=37.5).

Additionally, the etch recipe described in Table 1 may be used to remove the portion of the silicon nitride layer 216 that is outside of the spacer 221 (FIG. 2E), which is defined by the intersecting dash-dash line 217, one side 209 of the gate region 208, and the bottom 211 in FIG. 2D. The plasma etch operation thus permits certain portions of the silicon nitride layer 216 (the spacers 221) to remain. These remaining portions, the spacers 221, are shown being within the gate region 208, and are inside of the sides 209.

FIG. 2E shows that the plasma etch operation may be controlled so as to provide each of the spacers 221 with a selected width W in the gate direction 213. Such control selectively removes either more of the silicon nitride layer 216 that is within the gate region 208, in which case the width W is less, or such control selectively removes less of the silicon nitride layer 216, in which case the width W is greater. Observing FIG. 2E, as the width W of either or both of the spacers 221 becomes greater, the modified gate length L_{MG} become less and less. Conversely, as the width W of one or both of the spacers 221 is controlled to be less, the modified gate length L_{MG} is greater. This relationship may be expressed by Equation (1) as:

(1) L_{G}−W₁−W₂=L_{MG}; where W₁ is the width of the left spacer 221 shown in FIG. 2E, and W₂ is the width of the right

(2) Spacer 221 shown in FIG. 2E.

Further, FIG. 2E shows that after the spacers 221 have been defined, the structure shown in FIG. 2E (except for the oxide layer 202) is exposed to oxygen, such that a layer of gate oxide 222 is grown on the bottom 211.

In summary, then, FIGS. 2D and 2E illustrate the next operations in the process shown in FIG. 2A through 2C, in which the plasma etch operation removes all of the silicon nitride layer 216, except for the spacers 221, which are within the gate region 208. The spacers 221 function to reduce the initial gate length L_{G} of the gate region 208. In more detail, when each value of the width W of the spacers 221 is a measurable amount, the spacers 221 reduce the initial gate length _{LG} such that the modified gate length L_{MG} of the gate region 208 is less than the limit of the photolithography that is used to manufacture the devices 203, and the value of the modified gate length L_{MG} is less than the limit of such photolithography.

FIG. 2F shows further operations of the method shown in FIGS. 2A through 2E in which a polysilicon layer 223 is deposited on the semiconductor transistor structure 204 shown in FIG. 2E.

FIG. 2G illustrates the next operations in the process shown in FIGS. 2A through 2F, including a chemical mechanical operation (i.e., CMP) for planarizing the top surface 224 of the polysilicon layer 223. The CMP operation results in the structure shown in FIG. 2G in which there is no polysilicon on the top surface 218, and a gate portion 226 of the polysilicon layer 223 remains unetched in the center of the gate region 208 within (or between) the spacers 221 and above the gate oxide layer 222.

FIG. 2H shows further operations of the process shown in FIGS. 2A through 2G, including an oxide etch operation for removing the silicon dioxide layer 202 from opposite portions of the top surface 227 of the substrate 201, which portions are on opposite sides of the spacers 221. A wet etch in HF (hydrofluoric acid) is used to selectively remove the oxide layer 202. The recipe shown in Table 2 may be used for the plasma etch to remove the silicon dioxide layer 202.

TABLE 2
Dielectric (SiO₂) Ar/CHF₃/CF₄
Etch Chemistry

| | Top | Bottom | | | | | (He) |
|---|---|---|---|---|---|---|---|
| | Power | Power | Flow Rates | | | Pressure | backside pressure |
| | watts | watts | SCCM | | | MTorr | Torr |
| Preferred | 200-1000 | 400-1500 | Ar | CF₄ | CHF₃ | 10-50 | 5-30 |
| Range | | | 40-200 | 4-20 | 15-60 | | |
| More | 300-700 | 600-1000 | Ar | CF₄ | CHF₃ | 15-30 | 10-20 |
| Preferred | | | 80-150 | 6-12 | 25-45 | | |
| Range | | | | | | | |
| Most | 500 | 800 | Ar | CF₄ | CHF₃ | 20 | 15 |
| Preferred | | | 100 | 9 | 36 | | |

In this embodiment, the oxide etch operation is performed until the top surface 227 of the substrate 201 is exposed. Because the oxide etch operation is selective as to not remove the polysilicon gate portion 226, the gate portion 226 is not affected by the oxide etch operation. Further, since little, if any, of the silicon nitride spacers 221 are exposed to the oxide etch operation, the effect on the silicon nitride spacers 221 is not significant. Even if the silicon nitride spacers 221 are exposed to the oxide etch operation, because the selectivity of the oxide etch operation for silicon dioxide and silicon nitride (i.e., SiO₂/SiN=10) is about 10, only a fraction of the silicon nitride spacers 221 will be etched while substantially all of the silicon dioxide layer 202 is etched. Because of this selectivity, all of the silicon dioxide layer 202 surrounding the gate region 208 will be removed and only a very small portion, if any, of the silicon nitride spacers 221 will also be removed. As a result, after the oxide etch operation the transistor structure 204 will remain as shown in FIG. 2I, thereby providing room for an extension implant operation to be performed.

FIG. 2I illustrates further operations of the process shown in FIGS. 2A through 2H, including implanting source-drain extensions 228 below the spacers 221 to further define the modified gate length L_{MG} of the transistor structure 204. In more detail, as illustrated by the arrows 229, the implant operation for the source-drain extensions 228 is used to direct dopants at an angle phi relative to the top surface 227 of the substrate 201. The dopants directed at the angle phi pass through the spacers 221 and through an area 231 of the top surface 227 that is under the spacers 221. Then the dopants pass into the substrate 201, as illustrated by arrows 232. After the dopants pass the spacers 221 and the area 231, the dopants enter the substrate 201 and define the source-drain extension 228 having the implanted dopants, such that the extensions 228 may also be referred to as extension “implants”. In FIG. 2I, the source-drain extensions 228 are defined by dash-dash lines 233 which start at the intersection 219 (FIG. 2D). The lines 233 show the extensions 228 having a gate-length-defining end 234 curving downwardly and under the respective spacer 221 and then under the exposed top surface 227 of the substrate 201. As shown in FIG. 2I, the source-drain extensions 228 extend under each of the spacers 221 and have ends 234. Each end 234 is vertically aligned with the intersection 219 of the spacer 221 and the top surface 227 surface of the substrate.

In more detail, Table 3 below indicates that there is a relationship among the width W of each spacer 221, the angle phi at which the dopants are directed through each spacer 221, the dose of the directed dopants, the energy at which the dopants are so directed into the spacers 221, and the species (or dopant material). In general terms, it is to be understood that the wider the width W of the spacer 221, the greater the angle phi must be to provide the source-drain extension 228 having the end 234 extending in vertical alignment with the intersection 219 of the spacer 221 and the top surface 227 of the substrate 201. Further, the greater the width W of a spacer 221, the greater the energy which is required to have the dopants penetrate under spacer 221 and pass far enough to implant the dopants into the substrate 201. In particular, the spacer width W may be from 40 to 100 nm, and preferrably is from 50 to 80 nm. Table 3 shows that for the species arsenic/phosphorous and for a width W of 50 nm of a spacer 221 and with the dopant directed at angles between 20 and 60 degrees, the dopant energy may be from 5 to 60 KeV, and the dose may range from 1×10¹³ atoms/square cm to 1×10¹⁵ atoms/square cm.

TABLE 3
TABLE 3

| (50 nm) | | N-TYPE | | | P-TYPE | | |
|---|---|---|---|---|---|---|---|
| PREFERRED | ANGLE | DOSE | ENERGY | SPEC. | DOSE | ENERGY | SPEC. |
| | 30° | 5 × 10¹⁴ | 15 KeV | As | 5 × 10¹⁴ | 15 KeV | BF² |
| PREFERRED | 20-40° | 2 × 10¹⁴ to | 10 KeV to | As | 2 × 10¹⁴ | 10 KeV to | BF₂ |
| RANGE | | 8 × 10¹⁴ | 20 KeV | | 8 × 10¹⁴ | 20 KeV | |
| | | atoms/cm² | | | atoms/cm² | | |
| PREFERRED | 20-60° | 1 × 10¹³ to | 5-60 KeV | As/P | 1 × 10¹³ to | 5-60 KeV | BF₂/B |
| RANGE | | 1 × 10¹⁵ | | | 1 × 10¹⁵ | | |
| | | atoms/cm² | | | atoms/cm² | | |

As to the species BF₂/B between 20 and 60 degrees and 50 nm width W, the dopant energy may range from 5 to 60 KeV and the dose may range from 1×10¹³ to 1×10¹⁵ atoms/square cm. For these species, angle phi and width W, the dose is preferably 2×10¹⁴ atoms/square cm. Of the area 231 and the dopant energy is preferably 30 KeV. Table 4 shows the relationships among these parameters for a spacer width W of 70 nm. As compared to the 50 nm width, for the 70 nm width W there is a similar relationship variation among the angle phi, the dose of the dopants, and the energy at which the dopants are directed into and under the spacers 221.

TABLE 4

| Spacer | | | | | | | |
|---|---|---|---|---|---|---|---|
| 70 nm | | N-TYPE | | | P-TYPE | | |
| PREFERRED | ANGLE | DOSE | ENERGY | SPEC. | DOSE | ENERGY | SPEC. |
| | 30° | 5 × 10¹⁴ | 15 KeV | As | 5 × 10¹⁴ | 15 KeV | BF₂ |
| PREFERRED | 20-40° | 2 × 10¹³ to | 10 KeV to | As | 2 × 10¹⁴ | 10 KeV to | BF₂ |
| RANGE | | 8 × 10¹⁴ | 20 KeV | | 8 × 10¹⁴ | 20 KeV | |
| | | atoms/cm² | | | atoms/cm² | | |
| PREFERRED | 20-60° | 1 × 10¹³ to | 5-60 KeV | As/P | 1 × 10¹³ to | 5-60 KeV | BF₂/B |
| RANGE | | 1 × 10¹⁵ | | | 1 × 10¹⁵ | | |
| | | atoms/cm² | | | atoms/cm² | | |

FIG. 2J illustrates further operations of the process shown in FIGS. 2A through 2I, including source-drain implant operations for implanting source and drain dopants into and deeper than the source-drain extensions 228 to define source-drain diffusion regions 241. Ends 242 of the source-drain diffusion regions 241 are vertically aligned with outer walls of the spacers 221, and extend deeper into the substrate 201 than the source-drain extensions 228. These differences in the locations of the source-drain extensions 228 and the source-drain diffusion regions 241 are shown by dash-dash lines for the source-drain extensions 228 and dash-dot-dash lines 243 for the source-drain diffusion regions 241. After the dopants are provided, a rapid thermal annealing (RTA) operation is used to activate the implanted dopants.

FIG. 3A illustrates the transistor structure 204 including the source-drain diffusion regions 241 and the source-drain extensions 228 beneath the gate region 208. The source-drain extensions 228 are formed with the opposed ends 234, which cooperate with the spacers 221 and define the modified gate length L_{MG} of the gate 206, or the gate region 208. The gate length L_{MG} is less than the limit of the photolithography that is used to manufacture the transistor structures 204, since that limit is represented by the initial length L_{G} (FIG. 2E) between the outer walls of the spacers 221. In the example described above, such limit of photolithography, for example, is about 0.15 nm, whereas the combined width 2W of the spacers (assuming each spacer has about the same approximate width W), or the combined widths W₁ plus W₂, are deducted from the length L_{G} to obtain the value of the modified gate length L_{MG}. As described above with respect to the extension implant operation, the spacer width W may be in a range of 40 to 100 nm, such that according to Equation (1) the modified gate length L_{MG} may be from 80 to 200 nm less than the lithography-limited gate length L_{G} of about 0.15 micron in the exemplary situation described above.

FIG. 3B shows the resulting transistor structure 204, including the above-described gate 206 with the modified gate length L_{MG}, dielectric 246, conductive vias 247, and a metallization layer 248 for completing interconnects 249. Of course, to complete additional interconnects 249, one may deposit additional dielectric layers, conductive vias, and metallization layers to complete the semiconductor device 203.

In the foregoing description of the transistor structure, the material which is used to define the spacers 221 was said to preferrably be silicon nitride, and the gate-definition layer 202 (FIG. 2A) was said to be fabricated from silicon dioxide. It is to be understood that an alternate embodiment of the present invention contemplates fabricating the gate-definition layer 202 from silicon nitride, and the layer 216 that is used to define the spacers 221 from silicon dioxide. In the foregoing description of the fabrication of the transistor structure 204, the operation of implanting the dopants to define the source-drain extension was by directing the dopants through and under the spacers 221 after the silicon nitride layer 216 had been deposited and formed to define the spacers 221. It is to be understood that the function of the source-drain extensions may also be provided by extensions defined by an alternate operation. In particular, referring to FIG. 2D, during the deposition of the silicon nitride layer 216 which is later formed into the spacers 221, there may be in situ doping of the silicon nitride. For example, a suitable gas may be added to the deposition process to provide the dopants as the silicon nitride layer 216 is deposited. The dopants introduced by the gas are then annealed by a thermal diffusion operation to activate the implanted dopants. In all other functional respects, the source-drain extensions fabricated by this alternate operation are substantially the same as that of the implanted source-drain extensions described above.

Although the foregoing invention has been described in some detail for purposes of clarity of understanding, it will be apparent that certain changes and modifications may be practiced within the scope of the appended claims. Accordingly, the present embodiments are to be considered as illustrative and not restrictive, and the invention is not to be limited to the details given herein, but may be modified within the scope and equivalents of the appended claims.

What is claimed is:

1. A semiconductor transistor structure, comprising:
a substrate;
a modified gate structure defined over the substrate, the modified gate structure further comprising,
a polysilicon inner region having a top surface gate length and a bottom surface gate length that is disposed over the substrate, the bottom surface gate length having a modified gate length value that is shorter than a gate length value of the top surface gate length of the polysilicon inner region; and
at least one spacer defining a border around the polysilicon inner region, the border begin configured to define the modified gate length that is shorter than the gate length of the top surface gate length.

2. A semiconductor transistor structure as recited in claim 1, further comprising:
an extension implant located substantially below the at least one spacer that defines the border around the polysilicon inner region.

3. A semiconductor transistor structure as recited in claim 2, wherein the extension implants further define the modified gate length.

4. A semiconductor transistor structure as recited in claim 1, wherein the spacers are made from a material that is selected from one of a silicon nitride material and a silicon dioxide material.

5. A semiconductor transistor structure as recited in claim 1, wherein the top surface gate length is not less than 0.15 micron and the modified gate length is from 0.05 micron to just less than 0.15 micron.

6. A semiconductor transistor structure, comprising:
a substrate; and
a modified gate structure defined over the substrate, the modified gate structure further comprising,
spacers defining a gate border enclosing a top area having a top surface gate length of a first value and enclosing a bottom area having a bottom surface gate length of a second value, the gate border being tapered from the top area to the bottom area to define the second value of the bottom surface gate length adjacent to the bottom surface that is shorter than the second value of the top surface gate length; and
a polysilicon region received within the gate border and having a frustrum-like configuration extending from the top area to the bottom area over the substrate, the top area of the polysilicon region having the top surface gate length, the bottom area of the polysilicon region having the bottom surface gate length, the frustrum-like configuration being arranged so that the second value of the bottom surface gate length has a modified gate value that is shorter than the first value of the gate length of the top surface gate length of the polysilicon region.

7. A semiconductor transistor structure as recited in claim 6, further comprising:
an extension implant located substantially below each of the spacers that define the border around the polysilicon region.

8. A semiconductor transistor structure as recited in claim 6, wherein the extension implants further define the modified gate length.

9. A semiconductor transistor structure as recited in claim 6, wherein the spacers are made from a material that is selected from one of a silicon nitride material and a silicon dioxide material.

10. A semiconductor transistor structure as recited in claim 6, wherein the at least one spacer comprises two spacers, the two spacers being opposed and spaced to define the gate border and a series of successive gate lengths located between the top surface gate length and the bottom surface gate length, the taper of the gate border gradually reducing the value of the successive gate lengths from a maximum value of about equal to the first value gradually to a minimum value of about equal to the value of the modified bottom surface gate length.

11. A semiconductor transistor structure, comprising:
a gate definition layer having a top surface and a recess extending in the gate definition layer from the top surface to a bottom surface, the recess being defined by opposed gate walls that are spaced to define a preliminary gate length;
a spacer extending along each of the opposed gate walls within the recess, each of the spacers having a variable width that increases in value from the top surface to the bottom surface so that adjacent to the bottom surface the value of the preliminary gate length is modified as compared to the value of the preliminary gate length adjacent to the top surface, the modified preliminary gate length being less than the preliminary gate length adjacent to the top surface; and
a polysilicon region received in the recess between the opposed spacers so that the length of the region between the opposed walls varies from a large value adjacent to the top surface of the gate definition layer to a smaller value adjacent to the bottom surface, the smaller value being less than the large value.

12. A method for making a semiconductor transistor structure, comprising the operations of:
providing a substrate;
providing on the substrate a gate-defining layer having a gate-defining region provided with a critical dimension defining an initial value of a length of the gate defining region of the transistor structure, the critical dimension having a minimum value that is limited by at least photolithography characteristics of the operation of providing the gate-defining layer; and
reducing the initial value of the critical dimension by depositing into the gate-defining region a gate-length reducer structure to define a gate length of the transistor structure, wherein the gate length of the transistor structure is substantially less than the initial value of the critical dimension.

13. The method according to claim 12, wherein the critical dimension extends in a given direction relative to and over the substrate and the reducer structure has a reducer dimension in the given direction; the method further comprising the operations of:
directing implant material through the reducer structure and into the substrate to define a source-drain extension region in the substrate, the source-drain extension region being under the gate-length reducer structure.

14. The method according to claim 13, wherein the substrate is provided with a surface, the directing operation further comprising:
directing the implant material along selected paths, the selected paths being at an angle relative to the surface of the substrate so that the implant material is directed under the reducer structure, the angle of the selected paths being selected according to the value of the reducer dimension in the given direction.

15. A method of making a semiconductor transistor structure comprising the operations of:
providing a substrate;
depositing a gate-defining layer on the substrate;
defining in the gate-defining layer a gate region having a critical dimension, wherein the critical dimension has a value no less than approximately a minimum value achievable by the defining operation;
depositing into the gate-defining region a material for filling the gate region; and
selectively removing some of the material from the gate region so that a remainder of the material in the gate region has a width which decreases the value of the critical dimension and overlies the substrate to define a gate length having a value which is substantially less than the minimum value of the critical dimension.

16. The method according to claim 15, wherein the gate-defining region is made from one of a silicon dioxide and silicon nitride, and the material deposited into the gate-defining region is made from the other of the silicon dioxide and silicon nitride; the method further comprising the operation of:
directing at an angle relative to the surface of the substrate and into and through the remainder of the material and from the remainder of the material into the substrate implant impurities to define source-drain extensions in the substrate at locations under the remainder of the material, the angle being in a range from less than ninety degrees to more than zero degrees, the angle further being selected according to the width of the remainder of the material.

17. A method according to claim 15, wherein the operation of selectively removing some of the material from the gate region provides a variable decrease in the value of the critical dimension according to the distance of the remaining material from a surface of the substrate, and wherein the decrease in the value is greatest adjacent to the surface.

18. A method of manufacturing a semiconductor transistor structure having a gate length, the transistor structure including a gate-defining layer made from a first material and being capable of being formed by photolithographic operations, the method comprising the operations of:
using photolithography operations to define a gate region in the gate-defining layer, wherein a first direction of a length of the gate region corresponds to a second direction of the gate length of the transistor structure, and wherein the length of the gate region substantially exceeds the gate length of the transistor structure; and
providing in the gate region a second material extending across a portion of the length of the gate region to define in the gate region a gate region length-modifying structure having a width parallel to the length of the gate region that varies with the distance of the second material from a transistor structure reference surface so that adjacent to the reference surface the width has a maximum value;
wherein the gate length of the transistor structure is defined by the length of the gate region minus the width of the gate region length-modifying structure.

19. The method as recited in claim 18, wherein the transistor structure has a substrate supporting the gate-defining layer, the substrate extending under the gate region length-modifying structure, the method further comprising the operations of:
directing implant material through the gate region length-modifying structure into the substrate which extends under the gate region-modifying structure to form a source-drain extension structure in the substrate under the gate region length-modifying structure.

20. The method as recited in claim 19, wherein the directing operation is an ion implanting operation at a dosage, energy and angle relative to the reference surface that varies according to the value of the width of the gate region-modifying structure.
